(19) United States
(12) Patent Application Publication
(10) Pub. No.: US 2016/0374195 A1
(43) Pub. Date: Dec. 22, 2016

(54) COMPONENT FOR THE PROTECTION OF SENSITIVE SIGNALS, CORRESPONDING DEVICE AND METHOD

(71) Applicant: Ingenico Group, Paris (FR)

(72) Inventors: Michel ROSSIGNOL, Montleger (FR); Olivier BERTHIAUD, Cornas (FR)

(21) Appl. No.: 15/183,103

(22) Filed: Jun. 15, 2016

(30) Foreign Application Priority Data
Jun. 16, 2015 (FR) 1555513

(51) Int. Cl. H05K 1/02; H05K 1/11

(52) U.S. Cl. CPC H05K 1/0275; H05K 1/0213; H05K 1/115; H05K 2201/10734

(57) ABSTRACT

Component for the protection of sensitive signals, corresponding device and method, wherein the invention relates to an electronic component that comprises: an envelope forming a package; a printed circuit board; and a plurality of balls integrated into a ball grid array (BGA); said printed circuit board comprising at least one circuit defining at least one guard ring.

### BACKGROUND OF THE INVENTION

Field of the Invention

The invention relates to the field of the protection of sensitive signals on a printed circuit board. More particularly, the invention relates to the protection of sensitive signals at certain positions of a printed circuit board. The invention finds application in all printed circuit boards conveying data that can be subjected to an attempt at hacking or theft by an ill-intentioned individual. The described technique can be applied for example in payment terminals, where numerous sensitive signals are transmitted.

Description of the Related Art

The security of electronic data has become an indispensable factor in the designing of devices that contain or process confidential information. This is the case for example in specific terminals such as payment terminals, certain specific circuits of laptop computers or smartphones, pin pad data entry devices or biometrical devices (fingerprint readers).

For example, payment terminals that are used to process bank transactions must be certified according to the PCI (Payment Card Industry) standards. These standards make sure that the terminal is resistant to a certain number of attack scenarios. Some of these attack scenarios are aimed precisely at accessing certain sensitive signals that travel through payment terminals. Such signals can for example be the signals that travel between a bank card and the payment terminal. They could also be signals representing keys that are activated on a keyboard. In the payment terminals, as in the other electronic devices, the information is represented by signals transmitted to electronic components by conductive tracks of the printed circuit board (PCB). Over the years and with the continuous improvement of manufacturing techniques, printed circuit boards (on which the electronic components are mounted) have become often multilayered. This means that the signals are transmitted in a multiplicity of layers of the printed circuit board. Indeed, rather than greatly increasing the surface area of a printed circuit, it is more judicious to greatly increase the layers of printed circuit, thus giving a surface area equivalent to several times the real surface of the printed circuit while limiting their size. To make the signals travel from one layer to another, the technique known as the “via” technique is often used: a “via” is a hole into which a copper wire is inserted. This hole enables a signal to pass from one layer to another. There are vias that are used to connect only two layers superimposed on each other or vias that enable the connection of several layers or even all the layers of the printed circuit board.

Thus, the sensitive signals too travel by means of vias positioned on the PCB. To protect the sensitive signals, it is therefore necessary not only to protect the conductive tracks but also to protect the vias on the PCB. Indeed, it is relatively frequent for attack scenarios, as defined in industry, to plan for a phase of attack on the signals travelling through the vias.

A traditional solution for protecting sensitive signals in the vias is illustrated by way of information in FIG. 1. In this approach, a multilayer PCB is developed, with a small size called a “via cover”. The via layer or layers are soldered to the main PCB above it and are placed above the place at which the via is situated. In the example of FIG. 1, a PCB 100 has six layers: a first layer 101, called an upper layer, comprising a conductive track circuit and electronic components; a protection layer 102 taking the form of a lattice; a layer for transmitting a sensitive signal 110; a second protection layer 103, taking the form of a lattice and used to form a barrier with the first protection layer 102; a classic printed circuit board layer 104 which requires the presence of a sensitive signal; and finally a lower layer 105. In this example, two vias 111 and 112 are shown. They enable the sensitive signal to be made to travel between the layers. The layer 110 for routing sensitive signals is situated in the middle of two protection layers (lattice 1 and lattice 2). Thus, the tracks on the routing layer for routing sensitive signals are protected by two protection layers (lattice 1 and lattice 2). The multilayer PCB also comprises via covers 121, 122 (via cover 1 and via cover 2) situated above the vias 111, 112 deposited on the PCB.

The via cover elements 121, 122 are made traditionally with a specific PCB. In the example illustrated in FIG. 2, the via cover is up of a four-layer printed circuit board comprising two lattice layers 221, 222, a layer 210 for routing sensitive signals and a ground routing layer 230. The layer 210 for routing the sensitive signal is situated in the middle of the two lattice layers 221, 222: for greater security, the sensitive signal of the via hole is routed in this specific PCB. Two ball grid arrays (BGA) 241, 242 are disposed on the via cover and enable it to be soldered to a PCB.

A common example of manufacture also consists of not routing the sensitive signal of the via to this specific PCB. This example of use can be sub-optimal in certain conditions but it costs less to make.

Thus, a specific printed circuit board (the via cover) is soldered to the main electronic circuit. When a hacker wishes to access the via, he has to find a way to break through the protection offered by the via cover, and this proves to be generally complicated or lengthy. The protection offered as such is therefore relatively satisfactory.

However, these prior-art via covers are specifically designed and manufactured to fulfil the function of protection against access to sensitive signals by the vias laid out on the PCB. This necessitates the manufacture of specific parts for the manufacture of the electronic device. From the viewpoint of the management of the logistical chain, it is costly to maintain a large bill of materials (BOM) to manufacture a product. It is always desirable to reduce the number of these components in the list of parts necessary in order to reduce the logistical cost for the manufacture. Besides, the safety countermeasures within the via layers of the prior art are firstly complicated and secondly costly to implement: indeed, building a multilayer PCB is costly and having to build such multilayer PCBs solely for the needs of protection is unsatisfactory. Besides, the multilayer PCB has another drawback: it informs the hacker about the place in which the vias comprising the sensitive signals are situated. Indeed, for the hacker, it is enough to observe the main PCB to immediately detect the location of the vias. These are situated beneath the multilayer protection PCBs. This means that although they provide relatively efficient protection, the multilayer protection PCB gives the hacker information that he does not have, and this is, at the very least, sub-optimal in terms of effective protection.

### SUMMARY OF THE INVENTION

The present disclosure resolves the problems posed in the prior art. Indeed, the present disclosure relates to a method for protecting a sensitive signal, said sensitive signal being liable to travel in transit by means of a via of an electronic circuit comprising at least two layers.

The technique for protecting is implemented by an electronic component comprising: an envelope forming a package; a printed circuit board; and a plurality of balls integrated into a ball grid array.

According to the present disclosure, said printed circuit board comprises at least one circuit defining at least one guard ring.

Thus it is possible, by means of this component, to prevent the piercing of a printed circuit to which the component is fixed while at the same time having available a lateral protection against intrusion by means of a guard ring.

According to one particular characteristic, said printed circuit board furthermore comprises at least one linking circuit between a first connection and a second connection of said printed circuit board.

Thus, the component has an internal linking circuit used to withstand attempts at intrusion and/or to detect these attempts.

According to one particular characteristic, the linking circuit comprises at least one resistor of a predetermined value. Thus, any attempt to imitate the working of the component requires knowledge of this value, which is proper to the component and therefore complicated to obtain without having a copy of the component itself.

According to another aspect, the proposed technique also relates to a method for protecting an electrical signal travelling by means of a via of a multilayer printed circuit board, said via connecting at least two layers of said multilayer printed circuit. Such a method implements an electronic component as defined here above.

According to another complementary aspect, the proposed technique also relates to the use of an electronic component as defined here above to protect a signal travelling between at least two layers of a printed circuit board of an electronic device.

According to another aspect, the proposed technique also relates to an electronic data entry device. Such a device, namely an electronic component as defined here above, is affixed to a printed circuit board to protect the signal travelling between at least two layers of said printed circuit board.

Such a layout has the advantage of not enabling any ill-intentioned individual to have information on the position of the sensitive signal which is protected. Indeed, through the presence of an external envelope forming a package, the component cannot be distinguished from a similar component that fulfils a different function. It therefore becomes complicated for an ill-intentioned individual to identify the protection component relative to another component.

### BRIEF DESCRIPTION OF THE DRAWINGS

Other features and advantages shall appear more clearly from the following description of a particular embodiment of the disclosure, given by way of a simple illustratory and non-exhaustive example and from the appended figures, of which:

FIG. 1, already presented, is a view in section of a prior-art PCB for protecting sensitive signals;

FIG. 2, already presented, illustrates a prior art via cover made with a multilayer PCB;

FIG. 3a is a top view of a flip-chip BGA component implemented according to one embodiment of the invention;

FIG. 3b is a view in section of a flip-chip BGA component implemented according to the invention to protect a via;

FIG. 4 is a bottom view illustrating the way in which the balls of the flip-chip BGA component are soldered to obtain the protection effect sought;

FIG. 5 is a view in section of a PCB circuit equipped with a flip-chip BGA component (flip-chip via cover) according to the invention;

FIG. 6 illustrates an integrated printed circuit board defined according to the present technique and comprising two guard rings.

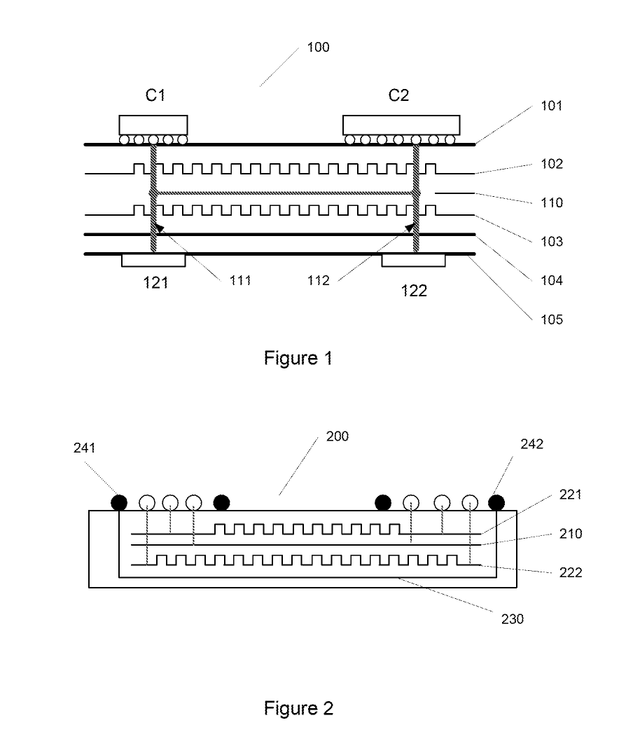

### DETAILED DESCRIPTION

The object of the present invention is to eliminate the need for a specific multilayer PCB to implement the function of via cover and to replace this PCB by a “traditional” component in order to reduce the costs of manufacture and optimize the process of soldering on copper.

The general principle of the described technique consists in using a BGA component in flip-chip technology in a particular use. As its name indicates, a flip chip is turned over in the BGA package. The mounting of the via cover by flip-chip BGA technology is more simple. The flip-chip BGAs are commonly used low-cost components. The use of these components to make the via cover reduces the logistical cost and the cost of the purchase for the manufacture of the electronic devices. In addition, the hacker is therefore no longer capable of detecting the via by a simple observation of the PCB: indeed, there is nothing to differentiate between one flip-chip component and another; the attacker cannot tell the difference between the different users of the flip chip by the naked eye.

The technique is more particularly implemented by means of an electronic component comprising an envelope forming a package, a printed circuit board and a plurality of balls integrated into a ball grid array. The printed circuit board comprises at least one circuit defining at least one guard ring. According to the embodiment, the component also comprises a linking circuit used to connect the component to a protection lattice present on the PCB to which the component is soldered. This makes it possible to take preventive action against attempts to violate the integrity of the component by detecting such violation through an aperture of the circuit defined by the lattice.

Another advantage of the solution lies in the fact of using classic BGA packages without having to develop a specific component. They are therefore usable in an industrial-scale component-mounting process like any other component. Thus, the use of this type of component (instead of specifically manufactured components) allows soldering or fixing the component directly, in a smooth and inexpensive process with other components (resistors, triacs, transistors, or the like).

Another object of the invention consists in improving security countermeasures while ensuring a simplified implementation and reduced cost. To this end, the invention consists in making secured signals travel in transit within the via cover made by flip-chip BGA technology. The signals that travel through the flip-chip BGA via cover are used to protect the sensitive signals and the via cover itself. According to one embodiment of the invention, at least two pins (BGA balls) of the flip-chip BGA via cover are connected to one another with a given series resistance (defined on the printed circuit component). Thus, the vias placed beneath the flip-chip package are protected against attacks made by unsoldering or piercing.

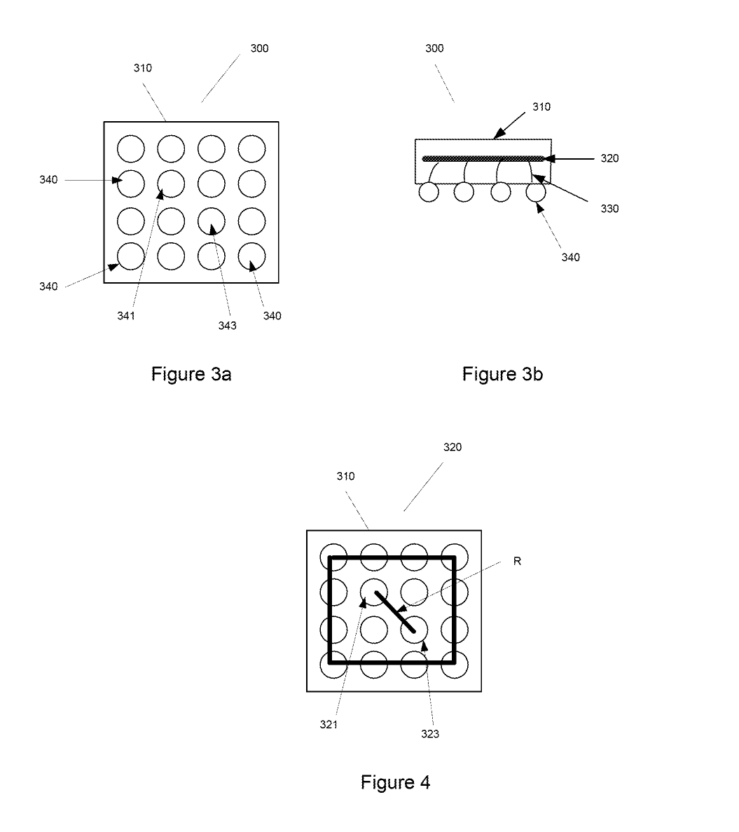

FIGS. 3a and 3b are respectively a top view and a view in section of the flip-chip BGA component according to one embodiment of a configuration according to the present technique. In this example, the flip-chip BGA component 300 comprises a package 310 preferably made of plastic, a matrix (for example 4×4) 340 of solder balls and bondings 330 connecting the solder balls 340 with the flip chip 320.

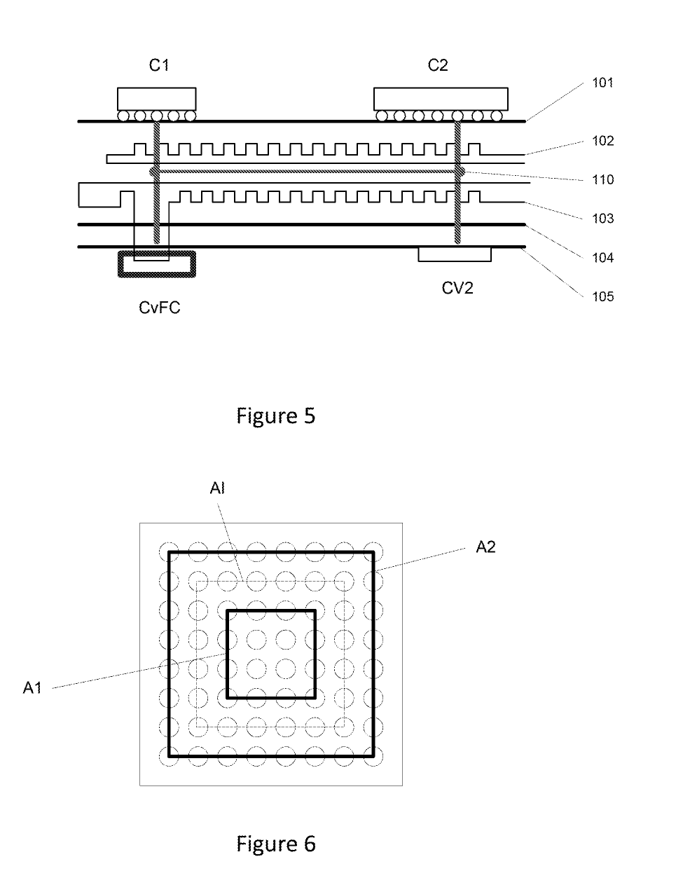

FIG. 4 illustrates a surface of the flip chip 320 opposite the ball grid array 310. On this flip-chip surface 230, there is a matrix of solder points corresponding to the ball grid array (BGA). The peripheral solder points are connected to each other and form a protection barrier connected to ground: this “barrier” makes it possible to detect any attempt to laterally pierce the component when it is soldered to the package. Two connections or solder points (for example 321 and 323) are connected by means of a resistor R having a predetermined value of resistance. These two solder points are respectively connected to the balls 341 and 343. During the mounting of the flip-chip BGA component on a PCB, the peripheral balls (340) are soldered to the PCB and connected to ground. The balls 341 and 343 are connected in series with a lattice of the PCB (see FIG. 5). Thus, for example, if a hacker inserts a probe into the component, a detector (for example a capacitive detector [not shown]) can detect a variation between the ground and the lattice. This attack by probe is therefore detected. When an attacker tries to dismantle the via cover and unsolder the balls of the flip-chip BGA component from the PCB, a detector connected to the lattice can also detect a circuit open on the lattice. This attack by dismantling is therefore detected. Even if an attacker connects two solder points of the lattice on the PCB during the dismantling of the flip-chip BGA component, the detector can always detect this attack because the value of resistance would not be the same as that of the resistor R.

FIG. 5 is a view in section of a PCB circuit equipped with a flip-chip BGA component (flip-chip via cover) which protects against access to sensitive signals by the vias. The flip-chip via cover (CvFC) is soldered beneath (or above) a via (conveying the signal to be protected) of the PCB. In this example, the lattice 103 which transmits a protection signal crosses the flip-chip via cover (CVFC) by means of solder balls 341 and 343 and the solder points 321 and 323 and the resistor R. The ground can be a copper track on the PCB layer, to which the flip-chip via cover is soldered. This ground track is connected by soldering to the peripheral balls of the ball grid array 340.

Naturally, this is only a presentation of a particular configuration. It can be envisaged for example to use a chip having a greater number of connections. It is possible for example to use a chip comprising 64 connections instead of 16 connections. An embodiment with 64 connections is presented with reference to FIG. 6. In this example of FIG. 6, the general principle of the technique described is preserved. Instead of only one ground ring, as presented here above, two ground rings (A1 and A2) are created. This embodiment has two advantages: the security of the unit is increased and the solidity of fastening of the component to the PCB is improved. Besides, it is also possible to make the signal of the lattice travel in transit through the intermediate ring (A1).

Other configurations or embodiments can also be implemented without departing from the framework of the invention.

1. Electronic component comprising:
an envelope forming a package;
a printed circuit board; and
a plurality of balls integrated into a ball grid array (BGA), wherein said printed circuit board comprises at least one circuit defining at least one guard ring.

2. Electronic component according to claim 1, wherein said printed circuit board furthermore comprises at least one linking circuit (CL) between a first connection and a second connection of said printed circuit board.

3. Electronic component according to claim 2, wherein a linking circuit comprises at least one resistor of a predetermined value.

4. Method for protecting an electrical signal travelling by means of a via of a multilayer printed circuit board, said via connecting at least two layers of said multilayer printed circuit board, method wherein it implements an electronic component according to claim 1.

5. Use of an electronic component according to claim 1 to protect a signal travelling between at least two layers of a printed circuit board of an electronic device.

6. Use of an electronic component according to claim 2 to protect a signal travelling between at least two layers of a printed circuit board of an electronic device.

7. Use of an electronic component according to claim 3 to protect a signal travelling between at least two layers of a printed circuit board of an electronic device.

8. Electronic data entry device wherein it comprises an electronic component according to claim 1, affixed to a printed circuit board to protect a signal travelling between at least two layers of said printed circuit board.

9. Electronic data entry device wherein it comprises an electronic component according to claim 2, affixed to a printed circuit board to protect a signal travelling between at least two layers of said printed circuit board.

10. Electronic data entry device wherein it comprises an electronic component according to claim 3, affixed to a printed circuit board to protect a signal travelling between at least two layers of said printed circuit board.
